(19) United States
(12) Patent Application Publication
(10) Pub. No.: US 2015/0188500 A1
(43) Pub. Date: Jul. 2, 2015

(54) POWER AMPLIFIER

(71) Applicant: SAMSUNG ELECTRO-MECHANICS CO., LTD., Suwon-Si (KR)

(72) Inventors: Seung Hoon KANG, Daejeon (KR); Chan Yong JEONG, Suwon-Si (KR); Gyu Suck KIM, Suwon-Si (KR); Song Cheol HONG, Daejeon (KR)

(21) Appl. No.: 14/341,532

(22) Filed: Jul. 25, 2014

(30) Foreign Application Priority Data
Dec. 30, 2013 (KR) 10-2013-0166742

(51) Int. Cl. H03F 1/32; H03F 1/34; H03F 3/45

(52) U.S. Cl. CPC H03F 1/3247; H03F 3/45179; H03F 1/3205; H03F 1/342; H03F 2201/3227; H03F 2200/129; H03F 2200/153; H03F 2203/45116

(57) ABSTRACT

A power amplifier may include: an amplification unit amplifying a power level of an input signal, a negative feedback circuit unit connected between an input terminal and an output terminal of the amplification unit and a linearization circuit unit connected between the negative feedback circuit unit and the input terminal of the amplification unit to predistort and linearize a signal from the negative feedback circuit unit, and to provide the signal to the input terminal of the amplification unit.

### CROSS-REFERENCE TO RELATED APPLICATION

This application claims the benefit of Korean Patent Application No. 10-2013-0166742 filed on Dec. 30, 2013, with the Korean Intellectual Property Office, the disclosure of which is incorporated herein by reference.

### BACKGROUND

The present disclosure relates to a power amplifier.

As transmission and reception systems require ever higher data transmission rate, multi-carrier wave schemes or relatively complicated digital modulation schemes are accordingly being employed therein. Such schemes require high degrees of linearity in transmitting and receiving terminals, and, inter alia, when a high power amplifier consuming a large amount of current performs transmissions, serious distortions may occur in a signal due to non-linearity characteristics in the power amplifier. For instance, in the case that a quadrature amplitude modulation (QAM) technique, a higher level technique than a BPSK modulation technique, is used, linearity of the power amplifier may be decreased.

In general, there is a trade-off between high linearity and high efficiency, and thus, a linear power amplifier having high efficiency is required. The two main indices used to evaluate the performance of linear power amplifiers are maximum output power (maximum linear output) with linearity, and efficiency when back-off is performed from maximum efficiency and output power, both of which are important design considerations.

Research into improving linearity of power amplifiers that transmits a signal without distortion is ongoing. Among methods derived therefrom, a method of inserting a linearizer into a power amplifier to linearizer signals is being widely used. In particular, a linearizer using a predistortion scheme is used in such a manner that non-linearity characteristics of a power amplifier to be linearized are tested and a non-linear circuit having characteristics opposed to the non-linearity of the power amplifier is provided at the input terminal of the power amplifier. This is an effective means of addressing the issue of non-linearity in high power amplifiers.

### SUMMARY

An aspect of the present disclosure may provide a power amplifier that improves linearity of low power to high power byway of providing a predistortion type linearization circuit unit with no insertion loss and having a small size in a power amplifier using a negative feedback circuit.

According to an aspect of the present disclosure, a power amplifier may include: an amplification unit amplifying a power level of an input signal; a negative feedback circuit unit connected between an input terminal and an output terminal of the amplification unit; and a linearization circuit unit connected between the negative feedback circuit unit and the input terminal of the amplification unit, predistorting and linearizing a signal from the negative feedback circuit unit, and providing the signal to the input terminal of the amplification unit.

The amplification unit may include an amplification transistor amplifying the power level of the input signal, and the amplification transistor has a first terminal connected to a ground, and a second terminal connected to a supply voltage terminal.

The power amplifier may further include: a first capacitor blocking DC components in the input signal; a second capacitor blocking DC components in an output signal from the amplification transistor; and an inductor connected in series between the second terminal of the amplification transistor and the supply voltage terminal.

The negative feedback circuit unit may include a feedback capacitor and a feedback resistor connected to each other in series, wherein the feedback capacitor has one terminal connected to the output terminal of the amplification transistor and the other terminal connected to the feedback resistor, and the feedback resistor has one terminal connected to the feedback capacitor and the other terminal connected to the linearization circuit unit.

The linearization circuit unit may include a linear transistor and a bias resistor connected to the control terminal of the linear transistor in series, wherein the linear transistor receives a bias signal via the bias resistor and receives a signal from the negative feedback circuit unit in the second terminal thereof.

The power amplifier may further include: an input impedance matching unit matching a signal transfer path between a signal input terminal from which the input signal is provided and the amplification unit with a predetermined impedance; and an output impedance matching unit matching a signal transfer path between the amplification unit and a signal output terminal to which an amplified signal is output with a predetermined impedance, wherein the input impedance matching unit includes a first capacitor blocking DC components in the input signal, and the output impedance matching unit includes a second capacitor blocking DC components in the output signals from the amplification transistor.

According to another aspect of the present disclosure, a power amplifier may include: a first amplification transistor amplifying a power level of an input signal from a signal input terminal; a second amplification transistor cascode-connected to the first amplification transistor, connected to an output terminal of the first amplification transistor, and amplifying an output signal from the first amplification transistor with a predetermined gain to output it to a signal output terminal; a negative feedback circuit unit connected between an output terminal of the second amplification transistor and an input terminal of the first amplification transistor and widening an amplification band of the first amplification transistor; and a linearization circuit unit connected between the negative feedback circuit unit and the input terminal of the first amplification transistor, receiving a bias signal, and predistorting and linearizing a signal from the negative feedback circuit unit to provide the signal to the input terminal of the first amplification transistor.

The negative feedback circuit unit may include a feedback capacitor and a feedback resistor connected to each other in series, wherein the feedback capacitor has one terminal connected to the output terminal of the second amplification transistor and the other terminal connected to the feedback resistor, and the feedback resistor has one terminal connected to the feedback capacitor and the other terminal connected to the linearization circuit unit.

The linearization circuit unit may include a linear transistor and a bias resistor connected to the control terminal of the linear transistor in series, wherein the linear transistor receives the bias signal via the bias resistor and receives a signal from the negative feedback circuit unit in the second terminal thereof.

The power amplifier may further include: an input impedance matching unit matching a signal transfer path between the signal input terminal from which the input signal is provided and the first amplification transistor with a predetermined impedance; and an output impedance matching unit matching a signal transfer path between the second amplification transistor and a signal output terminal to which an amplified signal is output with a predetermined impedance, wherein the input impedance matching unit includes a first capacitor blocking DC components in the input signal, and the output impedance matching unit includes a second capacitor blocking DC components in the output signals from the second amplification transistor.

According to another aspect of the present disclosure, a power amplifier may include: a first amplification unit including a first switch circuit unit amplifying a power level of a first input signal so as to output a first output signal, a first negative feedback circuit unit connected between an output terminal and an input terminal of the first switch circuit unit, and a first linearization circuit unit predistorting and linearizing an output signal from the first negative feedback circuit unit; and a second switch circuit unit amplifying a power level of a second input signal so as to output a second output signal, a second negative feedback circuit unit connected between an output terminal and an input terminal of the second switch circuit unit, and a second linearization circuit unit predistorting and linearizing an output signal from the second negative feedback circuit unit, wherein the first and second switch circuit units have a differential structure.

The power amplifier may further include: an input balloon unit converting an input signal from a signal input terminal into first and second input signals in antiphase, and an output balloon unit receiving the first and second output signals to generate an output signal and provides it to a signal output terminal.

The first switch circuit unit may include a first amplification transistor amplifying the power level of the first input signal, and a second amplification transistor cascode-connected to the first amplification transistor, connected to an output terminal of the first amplification transistor, and amplifying an output signal from the first amplification transistor with a predetermined gain so as to provide the signal to the signal output terminal; and the second switch circuit unit includes a third amplification transistor amplifying the power level of the second input signal, and a fourth amplification transistor cascode-connected to the third amplification transistor, connected to an output terminal of the third amplification transistor, and amplifying an output signal from the third amplification transistor with a predetermined gain so as to provide the signal to the signal output terminal.

The first linearization circuit unit may include a first linear transistor and a first bias resistor connected to the control terminal of the first linear transistor in series, wherein the first linear transistor receives the bias signal via the first bias resistor and receives a signal from the first negative feedback circuit unit in the second terminal thereof, and the second linearization circuit unit may include a second linear transistor and a second bias resistor connected to the control terminal of the second linear transistor in series, wherein the second linear transistor receives the bias signal via the second bias resistor and receives a signal from the second negative feedback circuit unit in the second terminal thereof.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a circuit diagram of an existing predistortion power amplifier;

FIG. 2 is an equivalent diagram of the linearizer among the elements of the power amplifier illustrated in FIG. 1;

FIG. 3 is a graph illustrating the operational principle of the linearizer among the elements of the power amplifier illustrated in FIG. 1 according to input power;

FIG. 4 is a block diagram illustrating a power amplifier according to an exemplary embodiment of the present disclosure;

FIG. 5A is a circuit diagram of the power amplifier illustrated in FIG. 4;

FIG. 5B is a circuit diagram of the power amplifier illustrated in FIG. 4 according to another exemplary embodiment of the present disclosure;

FIG. 6 is an equivalent circuit diagram of the linearization circuit unit among the elements of the power amplifier illustrated in FIG. 5A;

FIG. 7 is a graph illustrating transistor waveforms from the linearization circuit unit among the elements of the power amplifier illustrated in FIG. 5A according to levels of input signals.

FIG. 8 is a graph illustrating equivalent resistance values of a linear transistor among the elements of the power amplifier illustrated in FIG. 5A according to levels of input signals;

FIG. 9 is a circuit diagram of the power amplifier illustrated in FIG. 5A with input and output impedance matching units added thereto;

FIG. 10 is a circuit diagram of the power amplifier illustrated in FIG. 9;

FIG. 11 is a block diagram illustrating a power amplifier according to another exemplary embodiment of the present disclosure;

FIG. 12 is a graph illustrating a simulation result of linearity improvement of the power amplifier according to an exemplary embodiment of the present disclosure; and

FIG. 13 is a graph illustrating a simulation result of linearity improvement of the power amplifier according to an exemplary embodiment of the present disclosure.

### DETAILED DESCRIPTION

Hereinafter, embodiments of the present disclosure will be described in detail with reference to the accompanying drawings. The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art. Throughout the drawings, the same or like reference numerals will be used to designate the same or like elements.

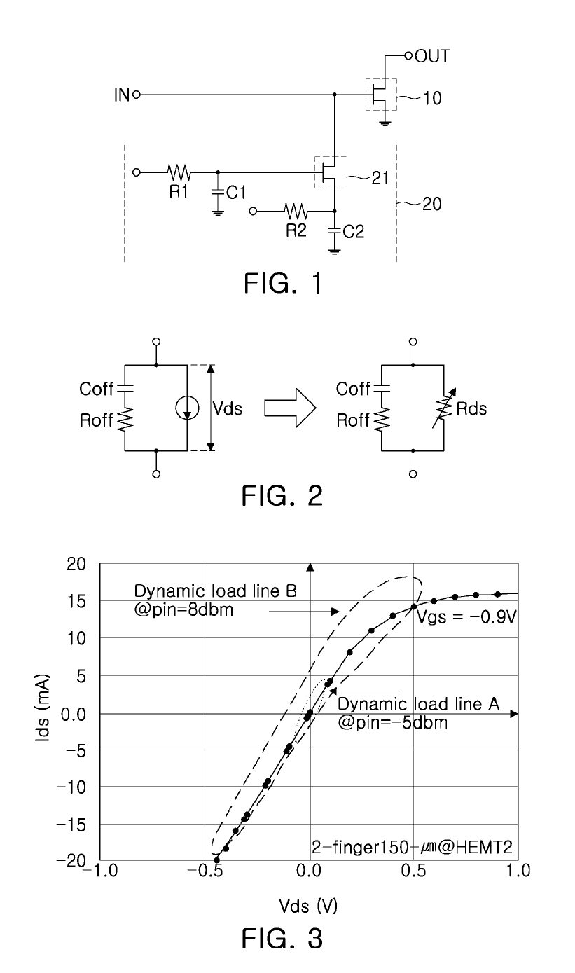

FIG. 1 is a circuit diagram of a predistortion power amplifier of the related art.

Referring to FIG. 1, the predistortion power amplifier may include an amplification transistor 10 and a linearizer 20.

The linearizer 20 may be connected to an input terminal of the amplification transistor 10.

The linearizer 20 may include a HEMT2 transistor 21, a first resistor R1 connected to the HEMT2 transistor 21 in series, and a first bypass capacitor C1. In addition, the linearizer 20 may further include a second resistor R2 connected to one terminal of the HEMT2 transistor 21 and a second bypass capacitor C2. The HEMT2 transistor 21 may be a field effect transistor (FET), for example. In the following description, it is assumed that the HEMT2 transistor 21 is a FET.

FIG. 2 is an equivalent circuit diagram of the linearizer 20 among the elements of the power amplifier illustrated in FIG. 1.

Referring to FIG. 2, in a cold-mode of the HEMT2 transistor 21, the drain-source voltage thereof is zero and thus no DC current flows and no DC power is consumed. The HEMT2 transistor 21 in the cold-mode may be represented by a capacitor Coff and a resistor Roff connected in series that are connected to a variable drain-source resistor Rds in parallel.

FIG. 3 is a graph illustrating the operational principle of the linearizer 20 among the elements of the power amplifier illustrated in FIG. 1 according to input power.

Referring to FIG. 3, the dynamic load line of the HEMT2 transistor 21 included in the linearizer 20 fluctuates with the linear region of the DC-DC voltage curve in a low input power mode. In the linear region, the gradient of the DC-DC voltage curve is constant and the linearizer 20 may have constant resistance.

In a high input power mode, on the other hand, the drain signal of the HEMT2 transistor 21 fluctuates greatly, such that the swing region of the dynamic load line extends to the non-linear (saturation) region. The dynamic load line is limited by the knee voltage and the drain-source current of the element, and, consequently, the resistance of the resistor Rds is increased.

As the resistance of the linearizer 20 is increased due to input power, gain expansion of the linearizer 20 at high input power occurs, and thus, amplification gain compression characteristics of the amplification transistor 10 may be improved.

When the linearizer 20 is operated at a low frequency, however, in order to supply a stable bias signal to the amplification transistor 10, the capacitance of a bypass capacitor has to be large enough, and this may increase the size of a chip substantially. Further, depending on impedance relationship between the linearizer 20 and the input terminal of the amplification transistor 10, a signal may flow into the HEMT2 transistor 21 included in the linearizer 20 connected to the amplification transistor 10 in parallel, such that insertion loss may occur in the linearizer 20 to thereby reduce power gain of the power amplifier and possibly reduce efficiency due to the reduced gain.

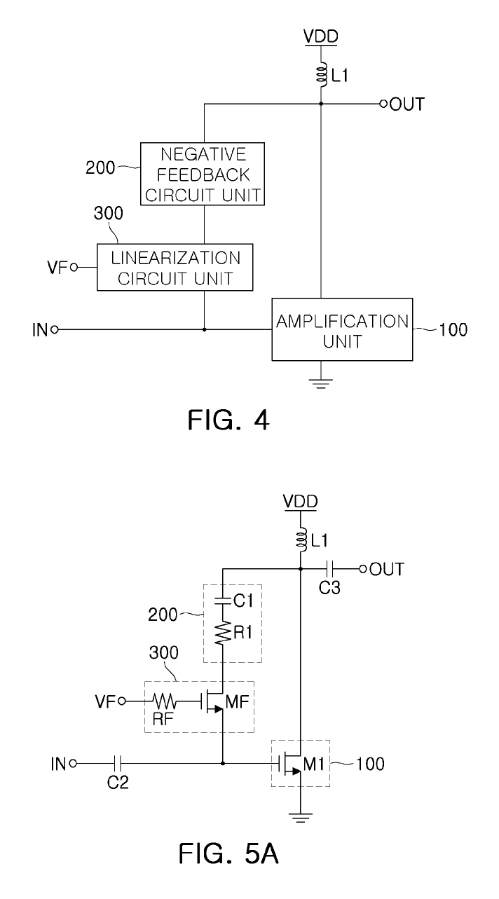

FIG. 4 is a block diagram illustrating a power amplifier according to an exemplary embodiment of the present disclosure.

Referring to FIG. 4, the power amplifier according to the exemplary embodiment may include an amplification unit 100, a negative feedback circuit unit 200, and a linearization circuit unit 300.

The amplification unit 100 may be connected between the supply voltage terminal VDD and ground, may amplify the power level of an input signal provided from a signal input terminal IN with a predetermined gain, and may provide the amplified input signals to a signal output terminal OUT.

The negative feedback circuit unit 200 may be connected between the input terminal and the output terminal of the amplification unit 100. Further, the linearization circuit unit 300 may be connected between the negative feedback circuit unit 200 and the input terminal of the amplification unit 100.

The linearization circuit unit 300 may predistort a signal from the negative feedback circuit unit 200 to linearize the signal and may provide the signal to the input terminal of the amplification unit 100.

Additionally, a power amplifier according to an exemplary embodiment of the present disclosure may further include a first inductor L1 connected the signal output terminal OUT and the supply voltage terminal VDD. The first inductor L1 may reduce AC components in the supply voltage from the supply voltage terminal VDD.

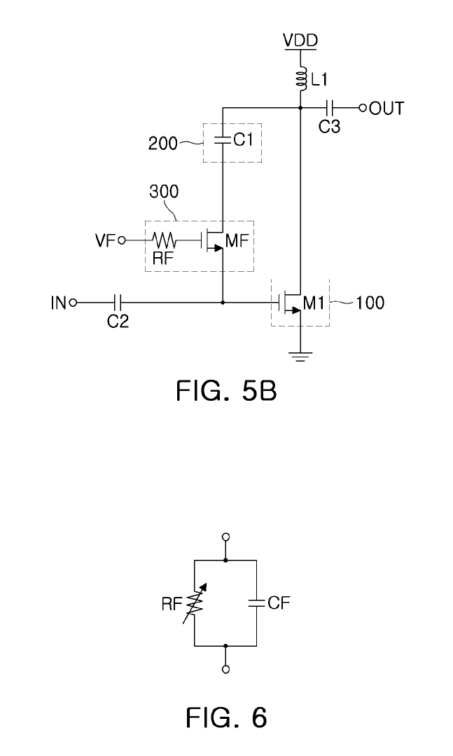

FIG. 5A is a circuit diagram of the power amplifier illustrated in FIG. 4.

Referring to FIG. 5A, the amplification unit 100 may include an amplification transistor M1 that amplifies the power level of an input signal with a predetermined gain.

The amplification transistor M1 may be a MOSFET, for example, and may have its source connected to a ground, and its drain connected to the supply voltage terminal VDD.

The negative feedback circuit unit 200 may include a feedback capacitor C1 and a feedback resistor R1 connected to each other in series. The feedback capacitor C1 may have one terminal connected to the output terminal of the amplification transistor M1 and may have the other terminal connected to the feedback resistor R1. The feedback resistor R1 may have one terminal connected to the feedback capacitor C1 and may have the other terminal connected to the linearization circuit unit 300.

The negative feedback circuit unit 200 thus configured may widen the amplification band of the amplification transistor M1 at the cost of reduced amplification gain may perform the R−C negative feedback function for improving stability to thereby improve linearity.

The linearization circuit unit 300 may include a linear transistor MF and a bias resistor RF connected to the control terminal of the linear transistor MF in series. The linear transistor MF may receive a bias signal via the bias resistor RF and may receive an output signal from the negative feedback circuit unit 200 at its drain.

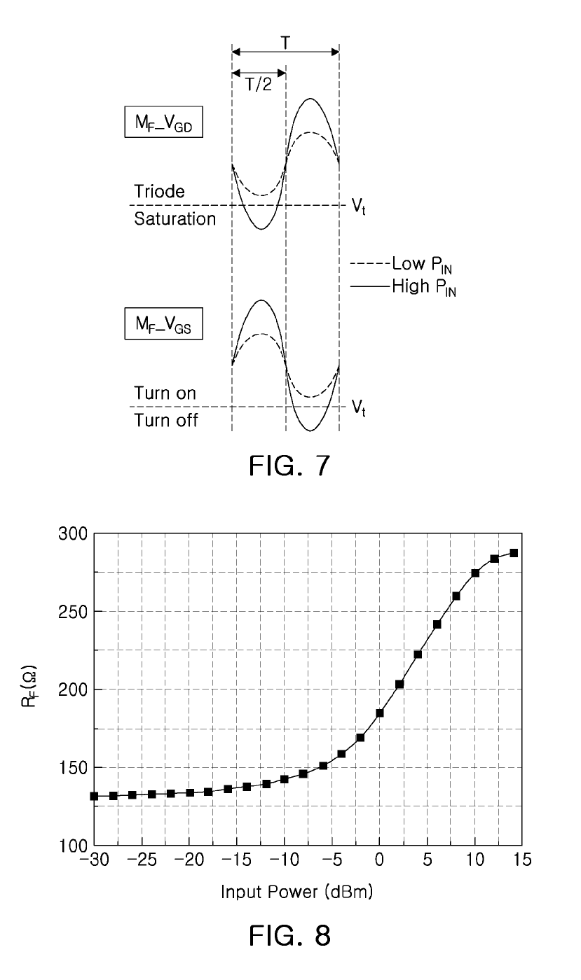

The linearization circuit unit 300 may behave as a predistortion type linearizer with no insertion loss while having a relatively small size, to thereby provide improvements over related art inventions. The operation of the linearization circuit unit 300 according to the exemplary embodiment will be described below with reference to FIGS. 6 and 7.

The power amplifier according to the exemplary embodiment may further include a first capacitor C2 that blocks DC components in an input signal provided from the signal input terminal IN, and a second capacitor C3 that blocks DC components in an output signal from the amplification transistor M1.

FIG. 5B is a circuit diagram of the power amplifier illustrated in FIG. 4 according to another exemplary embodiment of the present disclosure.

Referring to FIG. 5B, the negative feedback circuit unit 200 according to this exemplary embodiment may include a feedback capacitor C1. That is, unlike the power amplifier illustrated in FIG. 5A, the negative feedback circuit unit 200 of the power amplifier illustrated in FIG. 5B may only be configured with the feedback capacitor C1, without the feedback resistor R1.

This is due to the fact that an equivalent resistor RF of the linear transistor MF may replace the feedback resistor R1. Therefore, the linear transistor MF among the elements of the power amplifier according to another exemplary embodiment of the present disclosure may also perform the function of the feedback resistor R1 of the power amplifier illustrated in FIG. 5A.

FIG. 6 is an equivalent circuit diagram of the linearization circuit unit 300 among the elements of the power amplifier illustrated in FIG. 5A.

FIG. 7 is a graph illustrating transistor waveforms from the linearization circuit unit among the elements of the power amplifier illustrated in FIG. 5A according to levels of input signals.

Referring to FIGS. 6 and 7, the linearization circuit unit 300 among the elements of the power amplifier according to an exemplary embodiment of the present disclosure may include a linear transistor MF connected to the negative feedback circuit unit 200 in series, as described above, and a bias resistor RF.

It can be seen that the gate voltage and the drain voltage of the amplification transistor M1 are in anti-phase, and thus the source voltage and the drain voltage of the linear transistor MF are also in anti-phase.

When the level of an input signal is at low power, the linear transistor MF is biased so that it behaves in a linear region (Vgd>Vth) with being turned on (Vgs>Vth), and thus it has a constant resistance value.

When the level of the input signal is at high power, on the other hand, referring to FIG. 7, voltage at the drain of the linear transistor MF swings greatly during a first half period and thus the gate-drain voltage Vgd of the linear transistor MF may be expanded below a threshold voltage Vth. This means that the linear transistor MF enters the saturation region (non-linear region). This may result in a situation in which the amount of drain-source current of the linear transistor MF is limited and resistance thereof is increased.

During the second half period, voltage at the source of the linear transistor MF swings greatly and thus the gate-source voltage Vgs of the linear transistor MF may be expanded below a threshold voltage Vth. This means that the linear transistor MF enters the turn off region. This may result in that the amount of drain-source current of the linear transistor MF is limited and resistance thereof is increased.

In the power amplifier according to the related art, when the level of an input signal is at high level, voltage at one of the drain and source terminals of the HEMT2 transistor 21 included in the linearizer 20 swings greatly so that the resistance is increased, as described above with respect to FIG. 1. In the power amplifier according to the exemplary embodiment, however, when the level of an input signal is at high level, voltage at both nodes of the drain and source terminals of the linear transistor MF swings greatly so that the resistance may be increased more than in the related art.

Further, in the power amplifier including the negative feedback circuit unit 200, the amount of the current that is fed back is reduced as the resistance thereof is increased, so that the power gain of the power amplifier is increased. That is, according to this, when the level of input power is increased, an increase in the resistance of the bias resistance RF of the linear transistor MF leads to gain expansion, thereby improving gain compression characteristics of the power amplifier.

FIG. 8 is a graph illustrating equivalent resistance of the linear transistor MF among the elements of the power amplifier illustrated in FIG. 5A according to levels of input signals.

It can be seen from FIG. 8 that the equivalent resistance of the linear transistor MF included in the linearization circuit unit 300 is increased as the power level of an input signal provided from the signal input terminal IN is increased. By utilizing this, gain expansion characteristic is caused and thus the gain compression of the power amplifier according to the exemplary embodiment of the present disclosure may be improved.

Further, referring back to FIG. 1, in the power amplifier of the related art, the bias signal is applied to the gate terminal of the amplification transistor 10 by the linearizer 20, and accordingly at least two capacitors, i.e., the first and second bypass capacitors C1 and C2 are required for supplying the bias signals stably. Further, depending on impedance relationship between the linearizer 20 and the input terminal of the amplification transistor 10, a signal may flow into the HEMT2 transistor 21 included in the linearizer 20 connected to the amplification transistor 10 in parallel, such that insertion loss may occur in the linearizer 20 to thereby reduce power gain of the power amplifier and possibly reduce efficiency due to the reduced gain.

Again, referring to FIG. 5A, in the power amplifier according to the exemplary embodiment, a bias signal is directly applied to the gate terminal of the amplification transistor M1, and thus no separate bypass capacitor is necessary. This allows the size of the linearization circuit unit 300 to be reduced, and the size of a chip to be reduced accordingly.

In the power amplifier according to the exemplary embodiment of the present disclosure, a linearization circuit unit 300 is inserted in a signal path of the negative circuit unit 200 that is capable of improving stability and widening bandwidth, such that no signal leaks and, accordingly, loss in power gain and reduction in efficiency may be prevented.

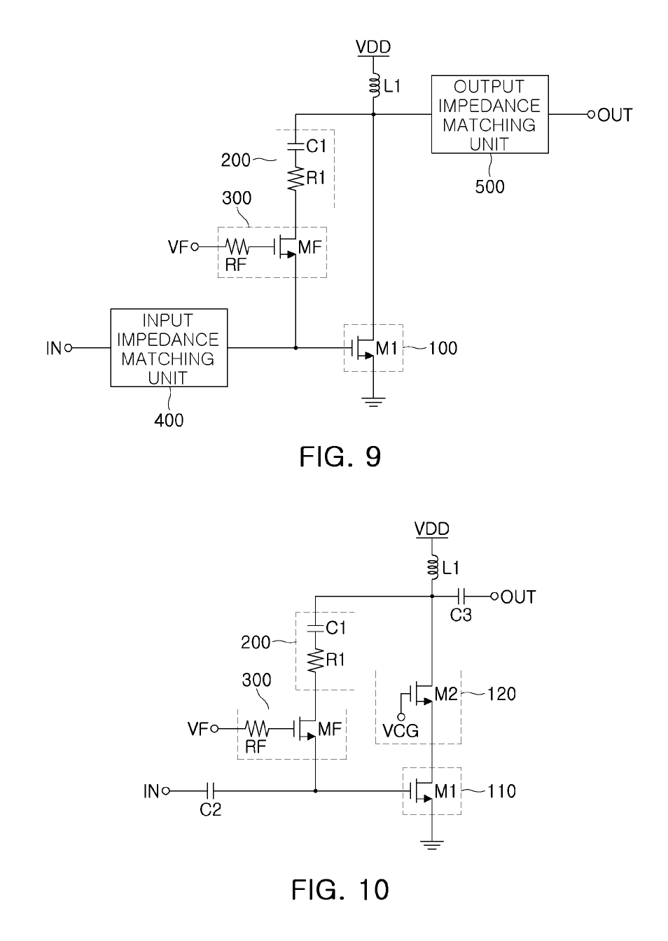

FIG. 9 is a circuit diagram of the power amplifier illustrated in FIG. 5A with input and output impedance matching units added thereto.

Referring to FIG. 9, the power amplifier according to the exemplary embodiment may further include an input impedance matching unit 400 that matches a signal transfer path between the signal input terminal IN from which the input signal is supplied and the amplification unit 100 to a predetermined impedance, and an output impedance matching unit 500 that matches a signal transfer path between the amplification unit 100 and the signal output terminal OUT to which the amplified signal is output to a predetermined impedance.

The input impedance matching unit 400 may further include a first capacitor C2 that blocks DC components in the input signal provided from the signal input terminal IN, and the output impedance matching unit 500 may further include a second capacitor C3 that blocks DC components in the output signal from the amplification transistor M1.

FIG. 10 is a circuit diagram of the power amplifier illustrated in FIG. 9.

Referring to FIG. 10, the power amplifier according to another exemplary embodiment of the present disclosure may include a first amplification transistor M1, a second amplification transistor M2, a negative feedback circuit unit 200, and a linearization circuit unit 300. In the following description, the detailed descriptions on the same functions as described above will not be made.

The first amplification transistor M1 may amplify the power level of an input signal that is provided from the signal input terminal IN with a predetermined gain to provide the signal to the second amplification transistor M2.

The second amplification transistor M2 may be cascode-connected to the first amplification transistor M1 and may amplify the output signal from the first amplification transistor M1 with a predetermined gain so as to provide the signal to the signal output terminal OUT. Since input and output signals at the gate terminal of the second amplification transistor M2 are in-phase, the phases of input and output of the cascode power amplifier according to the exemplary embodiment are equal to those of the power amplifier illustrated in FIG. 5A. This means that linearity may be effectively improved through the linearization circuit unit 300 applied to a cascode power amplifier.

Further, in the power amplifier according to another exemplary embodiment of the present disclosure, the first and second amplification transistors M1 and M2 are cascode-connected, thereby improving bandwidth and increasing the degree of isolation between input and output thereof.

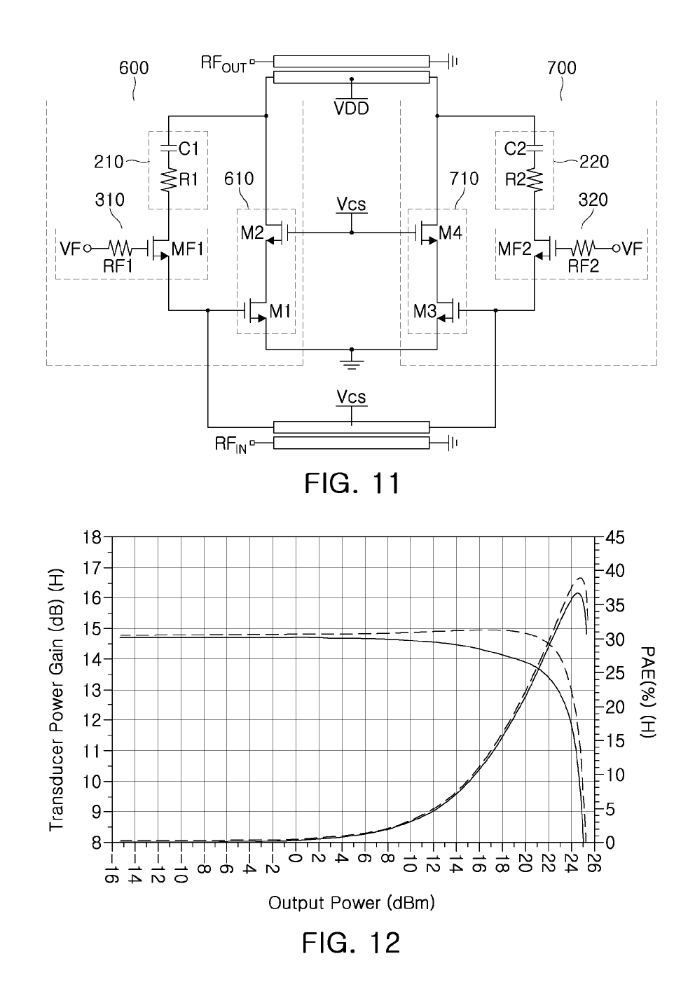

FIG. 11 is a block diagram illustrating a power amplifier according to another exemplary embodiment of the present disclosure.

Referring to FIG. 11, the power amplifier according to this exemplary embodiment may include a first amplification unit 600 and a second amplification unit 700.

The first and second amplification units 600 and 700 may be a differential structure to each other.

The first amplification unit 600 may include a first switch circuit unit 610 that amplifies the power level of a first input signal so as to output a first output signals, a first negative feedback circuit unit 210 that is connected between the output terminal and the input terminal of the first switch circuit unit 610, and a first linearization circuit unit 310 that predistorts an output signal from the first negative feedback circuit unit 210 so as to linearize it.

The first switch circuit unit 610 may include a first amplification transistor M1 that amplifies the power level of the first input signal, and a second amplification transistor M2 that is cascode-connected to the first amplification transistor M1, connected to the output terminal of the first amplification transistor, and amplifies the output signal from the first amplification transistor with a predetermined gain so as to provide the signal to the signal output terminal.

The first linearization circuit unit 310 may include a first linear transistor MF1 and a first bias resistor RF1 connected to the control terminal of the first linear transistor MF1 in series.

The first linear transistor MF1 may receive the bias signal via the first bias resistor RF1 and may receive a signal from the first negative feedback circuit unit 210 at the drain of the first linear transistor MF1.

The second amplification unit 700 may include a second switch circuit unit 710 that amplifies the power level of a second input signal so as to output a second output signal, a second negative feedback circuit unit 220 that is connected between the output terminal and the input terminal of the second switch circuit unit 710, and a second linearization circuit unit 320 that predistorts an output signal from the second negative feedback circuit unit so as to linearize it.

The second switch circuit unit 610 may include a third amplification transistor M3 that amplifies the power level of the second input signal, and a fourth amplification transistor M4 that is cascode-connected to the third amplification transistor M3, connected to the output terminal of the third amplification transistor M3, and amplifies the output signal from the third amplification transistor M3 with a predetermined gain so as to provide the signal to the signal output terminal.

The second linearization circuit unit 320 may include a second linear transistor MF2 and a second bias resistor RF3 connected to the control terminal of the second linear transistor in series.

The second linear transistor MF2 may receive the bias signal via the second bias resistor RF2 and may receive a signal from the second negative feedback circuit unit 220 at the drain of the second linear transistor MF2.

Further, a power amplifier according to another exemplary embodiment of the present disclosure may further include an input balloon unit that converts an input signal from a signal input terminal into first and second input signals in antiphase, and an output balloon unit that receives the first and second output signals to generate an output signal and provides it to a signal output terminal.

That is, in the power amplifier according to this exemplary embodiment of the present disclosure, the first and second amplification units are formed as differential structures, thereby preventing power gain reduction due to bond wire inductance. In addition, since the first and second linearization circuit units 310 and 320 have relatively small sizes, they may not affect the overall chip size.

FIG. 12 is a graph illustrating a simulation result (1 tone) of linearity improvement of the power amplifier illustrated in FIG. 11. The dashed line represents the linearity of the power amplifier of the related art, and the solid line represents the linearity of the power amplifier having differential structure according to the exemplary embodiment of the present disclosure.

That is, FIG. 12 shows the simulation result (1 tone test) by comparing the power amplifier having the differential structure illustrated in FIG. 10 with the power amplifier of the related art so as to see the effect of linearity improvement.

In the power amplifier of the related art, although stability is obtained, gain compression occurs early so that linearity deteriorates.

In contrast, in the power amplifier having the differential structure according to the exemplary embodiment of the present disclosure, the gain is rarely changed even at high output power, and linear output power when P1dB is met is 23.3 dBm, which is increased by about 2.5 dB compared to the circuit of the related art. In addition, it can be seen that efficiency is also increased from 24.2% to 34.5% by 10.3%. Further, due to increased gain at the high output power, the maximum efficiency is also increased from 36.7% to 39% by 2.3%.

Moreover, it can be seen that power gain of the power amplifier according to the exemplary embodiment is similar to that of the related art because there is no insertion loss.

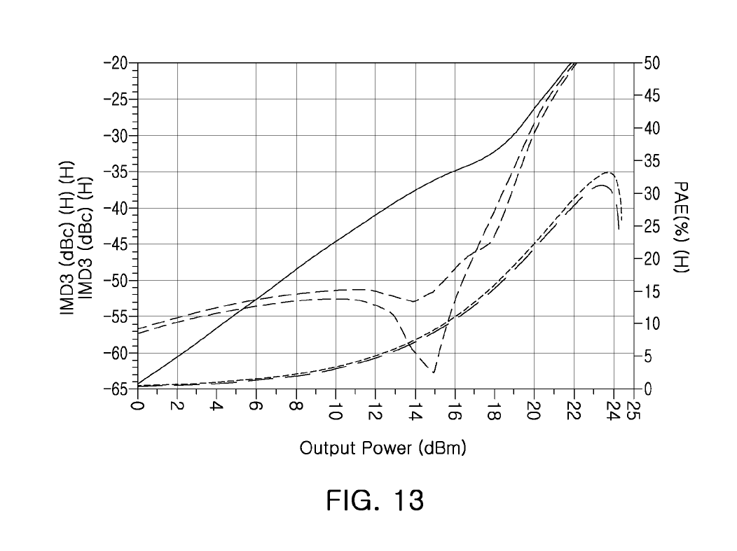

FIG. 13 is a graph illustrating a simulation result (2 tones) of linearity improvement of the power amplifier illustrated in FIG. 11. The dashed line represents the linearity of the power amplifier of the related art, and the solid line represents the linearity of the power amplifier having differential structure according to the exemplary embodiment of the present disclosure.

That is, FIG. 13 shows the simulation result (2-tone test) by comparing the power amplifier having the differential structure illustrated in FIG. 10 with the power amplifier of the related art so as to see the effect of linearity improvement.

As can be seen from FIG. 13, the power amplifier having the differential structure according to the exemplary embodiment of the present disclosure exhibits good intermodulation distortion IMD3 performance over low power points to high power points. Linear output power that meets IMD3<−40 dBc is 18 dBm, which is increased by about 5.5 dB compared to the linear output in the related art is 12.5 dBm.

Further, as can be seen from FIGS. 12 and 13, the power amplifier having the differential structure according to the exemplary embodiments of the present disclosure do not have reduction in efficiency due to increase in linearity. This is due to the fact that the first and second linearization circuit units 310 and 320 do not consume additional current.

As described above, the power amplifier according to the exemplary embodiment of the present disclosure may improve linearity over entire output power regions, improve maximum linearity output points, and reduce the size of a chip thereby to save manufacturing cost.

As set forth above, according to exemplary embodiments of the present disclosure, linearity may be improved from low power to high power and accordingly maximum linear output power and maximum linear efficiency may be improved. Moreover, the power amplifier according to exemplary embodiments of the present disclosure has no insertion loss and may apply a stable bypass signal even without a bypass capacitor so that an area of a chip may be effectively utilized.

In addition, linearity may be improved overall output regions, maximum linear output points may be improved, and the size of a chip may be reduced to thereby reduce manufacturing cost.

While exemplary embodiments have been shown and described above, it will be apparent to those skilled in the art that modifications and variations could be made without departing from the spirit and scope of the present disclosure as defined by the appended claims.

What is claimed is:

1. A power amplifier, comprising:
an amplification unit configured to amplify a power level of an input signal;
a negative feedback circuit unit connected between an input terminal and an output terminal of the amplification unit; and
a linearization circuit unit connected between the negative feedback circuit unit and the input terminal of the amplification unit to predistort and linearize a signal from the negative feedback circuit unit, and to provide the signal to the input terminal of the amplification unit.

2. The power amplifier of claim 1, wherein the amplification unit includes an amplification transistor amplifying the power level of the input signal, and the amplification transistor has a first terminal connected to a ground, and a second terminal connected to a supply voltage terminal.

3. The power amplifier of claim 2, further comprising:
a first capacitor blocking DC components in the input signal;
a second capacitor blocking DC components in an output signal from the amplification transistor; and
an inductor connected in series between the second terminal of the amplification transistor and the supply voltage terminal.

4. The power amplifier of claim 2, wherein the negative feedback circuit unit includes a feedback capacitor and a feedback resistor connected to each other in series, wherein the feedback capacitor has one terminal connected to the output terminal of the amplification transistor and the other terminal connected to the feedback resistor, and the feedback resistor has one terminal connected to the feedback capacitor and the other terminal connected to the linearization circuit unit.

5. The power amplifier of claim 1, wherein the linearization circuit unit includes a linear transistor and a bias resistor connected to a control terminal of the linear transistor in series, wherein the linear transistor receives a bias signal via the bias resistor and receives a signal from the negative feedback circuit unit in the second terminal thereof.

6. The power amplifier of claim 1, further comprising:
an input impedance matching unit matching a signal transfer path between a signal input terminal from which the input signal is provided and the amplification unit with a predetermined impedance; and
an output impedance matching unit matching a signal transfer path between the amplification unit and a signal output terminal to which an amplified signal is output with a predetermined impedance,
wherein the input impedance matching unit includes a first capacitor blocking DC components in the input signal, and the output impedance matching unit includes a second capacitor blocking DC components in the output signals from the amplification transistor.

7. A power amplifier, comprising:
a first amplification transistor amplifying a power level of an input signal from a signal input terminal;
a second amplification transistor cascode-connected to the first amplification transistor, connected to an output terminal of the first amplification transistor, and amplifying an output signal from the first amplification transistor with a predetermined gain to output it to a signal output terminal;
a negative feedback circuit unit connected between an output terminal of the second amplification transistor and an input terminal of the first amplification transistor and widening an amplification band of the first amplification transistor; and
a linearization circuit unit connected between the negative feedback circuit unit and the input terminal of the first amplification transistor, receiving a bias signal, and predistorting and linearizing a signal from the negative feedback circuit unit to provide the signal to the input terminal of the first amplification transistor.

8. The power amplifier of claim 7, wherein the negative feedback circuit unit includes a feedback capacitor and a feedback resistor connected to each other in series, wherein the feedback capacitor has one terminal connected to the output terminal of the second amplification transistor and the other terminal connected to the feedback resistor, and the feedback resistor has one terminal connected to the feedback capacitor and the other terminal connected to the linearization circuit unit.

9. The power amplifier of claim 7, wherein the linearization circuit unit includes a linear transistor and a bias resistor connected to a control terminal of the linear transistor in series, wherein the linear transistor receives the bias signal via the bias resistor and receives a signal from the negative feedback circuit unit in the second terminal thereof.

10. The power amplifier of claim 7, further comprising:
an input impedance matching unit matching a signal transfer path between the signal input terminal from which the input signal is provided and the first amplification transistor with a predetermined impedance; and
an output impedance matching unit matching a signal transfer path between the second amplification transistor and a signal output terminal to which an amplified signal is output with a predetermined impedance,
wherein the input impedance matching unit includes a first capacitor blocking DC components in the input signal, and the output impedance matching unit includes a second capacitor blocking DC components in the output signals from the second amplification transistor.

11. A power amplifier, comprising:
a first amplification unit including a first switch circuit unit amplifying a power level of a first input signal so as to output a first output signal, a first negative feedback circuit unit connected between an output terminal and an input terminal of the first switch circuit unit, and a first linearization circuit unit predistorting and linearizing an output signal from the first negative feedback circuit unit; and
a second switch circuit unit configured to amplify a power level of a second input signal so as to output a second output signal, a second negative feedback circuit unit connected between an output terminal and an input terminal of the second switch circuit unit, and a second linearization circuit unit predistorting and linearizing an output signal from the second negative feedback circuit unit, wherein the first and second switch circuit units have a differential structure.

12. The power amplifier of claim 11, further comprising:
an input balloon unit converting an input signal from a signal input terminal into first and second input signals in antiphase, and an output balloon unit receiving the first and second output signals to generate an output signal and provides it to a signal output terminal.

13. The power amplifier of claim 11, wherein:
the first switch circuit unit includes a first amplification transistor amplifying the power level of the first input signal, and a second amplification transistor cascode-connected to the first amplification transistor, connected to an output terminal of the first amplification transistor, and amplifying an output signal from the first amplification transistor with a predetermined gain so as to provide the signal to the signal output terminal; and
the second switch circuit unit includes a third amplification transistor amplifying the power level of the second input signal, and a fourth amplification transistor cascode-connected to the third amplification transistor, connected to an output terminal of the third amplification transistor, and amplifying an output signal from the third amplification transistor with a predetermined gain so as to provide the signal to the signal output terminal.

14. The power amplifier of claim 11, wherein:
the first linearization circuit unit includes a first linear transistor and a first bias resistor connected to a control terminal of the first linear transistor in series, wherein the first linear transistor receives the bias signal via the first bias resistor and receives a signal from the first negative feedback circuit unit in the second terminal thereof, and
the second linearization circuit unit includes a second linear transistor and a second bias resistor connected to a control terminal of the second linear transistor in series, wherein the second linear transistor receives the bias signal via the second bias resistor and receives a signal from the second negative feedback circuit unit in the second terminal thereof.
